(19) United States
(12) Patent Application Publication
(10) Pub. No.: US 2005/0052197 A1
(43) Pub. Date: Mar. 10, 2005

(54) Multi-tool manager

(76) Inventor: Cory Watkins, Chanhassen, MN (US)

Correspondence Address: DICKE BILLIG & CZAJA, PLLC;ATTN: JOHN VASUTA, 100 SOUTH FIFTH STREET, SUITE 2250, MINNEAPOLIS, MN, 55402, US

(21) Appl. No.: 10/890,928

(22) Filed: Jul. 14, 2004

Related U.S. Application Data
(60) Provisional application No. 60/486,955, filed on Jul. 14, 2003.

(51) Int. Cl. G01R 31/26

(52) U.S. Cl. 324/765

(57) ABSTRACT

A semiconductor inspection system comprises a first inspection tool communicatively coupled to a network, a second inspection tool communicatively coupled to the network, and a multi-tool manager communicatively coupled to the network. The multi-tool manager is configured to monitor the first inspection tool and the second inspection tool through the network.

### CROSS-REFERENCE TO RELATED APPLICATIONS

This application claims the benefit of U.S. Provisional Application Ser. No. 60/486,955, filed Jul. 14, 2003.

### BACKGROUND

1. Technical Field

The present invention relates to a multi-tool manager adapted to monitor and/or control two or more semiconductor inspection tools communicatively coupled to a network.

2. Background Information

Over the past several decades, the semiconductor has exponentially grown in use and popularity. The semiconductor has in effect revolutionized society by introducing computers, electronic advances, and generally revolutionizing many previously difficult, expensive and/or time consuming mechanical processes into simplistic and quick electronic processes. This boom in semiconductors has been fueled by an insatiable desire by business and individuals for computers and electronics, and more particularly, faster, more advanced computers and electronics whether it be on an assembly line, on test equipment in a lab, on the personal computer at one's desk, or in the home electronics and toys.

The manufacturers of semiconductors have made vast improvements in end product quality, speed and performance as well as in manufacturing process quality, speed and performance. However, there continues to be demand for faster, more reliable and higher performing semiconductors. To assist these demands, better inspection is necessary to increase yields. Better inspection is inspection that assists in driving down the cost of ownership of a chip fab.

Most current inspection tools are designed for a specific single type of inspection, metrology or review such as any one of the following: two dimensional (2D) front side, three dimensional (3D) front side, edge, back side, review, metrology, wafer bowing, microscopy and the like, and are often also designed for a particular stage of the wafer processing such as any one of the following: bare wafer, photolithography, active topography, metal interconnect, etch, chemical mechanical polish (CMP), final passivation, etc. Typically, each tool is a stand alone independent tool requiring localized configuration and operation. As a result, configuring multiple tools and coordinating processes between multiple tools is often a time consuming and difficult process. It is desirable to provide an inspection tool management system to monitor, coordinate, and control multiple inspection tools from a single location.

### SUMMARY

One embodiment of the present invention provides a semiconductor inspection system. The semiconductor inspection system comprises a first inspection tool communicatively coupled to a network, a second inspection tool communicatively coupled to the network, and a multi-tool manager communicatively coupled to the network. The multi-tool manager is configured to monitor the first inspection tool and the second inspection tool through the network.

### BRIEF DESCRIPTION OF THE DRAWINGS

Preferred embodiments of the invention, illustrative of the best mode in which applicant has contemplated applying the principles, are set forth in the following description and are shown in the drawings and are particularly and distinctly pointed out and set forth in the appended claims.

FIG. 1 is a block diagram illustrating one embodiment of multiple semiconductor inspection tools linked to a multi-tool manager.

FIG. 2 is a diagram illustrating one embodiment of the multi-tool manager.

FIG. 3 is a diagram illustrating one embodiment of a semiconductor inspection tool.

FIG. 4 is a diagram illustrating another embodiment of a semiconductor inspection tool.

Similar numerals refer to similar parts throughout the drawings.

### DETAILED DESCRIPTION

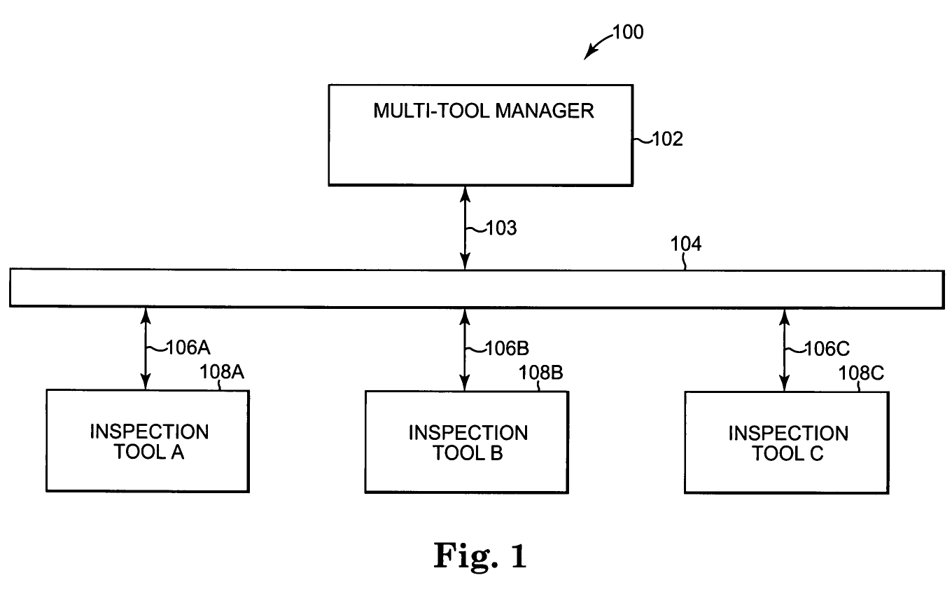

FIG. 1 is a block diagram illustrating one embodiment of a system 100 including multiple semiconductor inspection tools linked to a multi-tool manager. System 100 includes multi-tool manager 102, network 104, and two or more inspection tools, such as inspection tool A 108A, inspection tool B 108B, and inspection tool C 108C (collectively referred to as inspection tools 108). In one embodiment, system 100 includes N inspection tools 108, where N is an integer greater than one. Multi-tool manager 102 is electrically coupled to network 104 through communication link 103. Network 104 is electrically coupled to inspection tools 108A-108C through communication links 106A-106C, respectively.

Multi-tool manager 102 configures, controls, and coordinates operations between inspection tools 108A-108C. In one embodiment, multi-tool manager 102, through network 104, configures each tool 108A-108C, monitors the operation of each tool 108A-108C, and controls the operation of each tool 108A-108C. In addition, in one form of the invention, multi-tool manager 102 is configured to enable and disable each tool 108A-108C and troubleshoot each tool 108A-108C through network 104.

In one embodiment, network 104 is an intranet, such as a local area network (LAN), internet, or any other suitable network for transmitting signals between multi-tool manager 102 and inspection tools 108A-108C.

Inspection tools 108A-108C are any suitable semiconductor inspection tools. In one form of the invention, inspection tools 108A-108C are automated systems that are configured to inspect substrates, such as semiconductor wafers and semiconductor die. In one embodiment, inspection tools 108A-108C include semiconductor wafer inspection systems comprising one or more of the following: a two dimensional front side inspection system, a three dimensional front side inspection system, an edge inspection system, and a back side inspection system. In one embodiment, inspection tools 108A-108C comprise one or more of the following: a metrology system, a wafer bowing system, a microscopy system, a film thickness system, a chemical mechanical polishing dishing system, a chemical mechanical polishing erosion system, a macro critical dimension metrology system, and a micro critical dimension metrology system. Inspection tools 108A-108C, in one embodiment, are used for inspecting wafers at one or more of a bare wafer stage, a photolithography stage, an active topography stage, a metal interconnect stage, an etch stage, a chemical mechanical polish stage, and a final passivation stage.

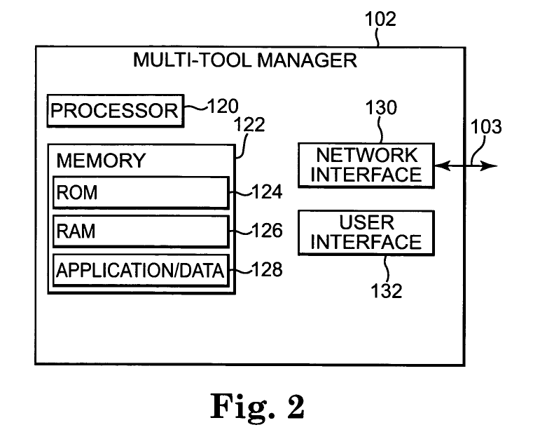

FIG. 2 is a block diagram illustrating one embodiment of multi-tool manager 102. In one embodiment, multi-tool manager 102 is implemented with a computer system. Multi-tool manager 102 includes a processor 120, a memory 122, a network interface 130, and a user interface 132. Memory 122 includes a read only memory (ROM) 124, a random access memory (RAM) 126, and an application/data memory 128. Network interface 130 is communicatively coupled to network 104 (FIG. 1) through communication link 103.

Multi-tool manager 102 executes an application program for implementing functions of multi-tool manager 102. The application program is loaded from application/data memory 128 or any other computer readable medium. Processor 120 executes commands and instructions for implementing functions of multi-tool manager 102. In one embodiment, ROM 124 stores an operating system for multi-tool manager 102, and RAM 126 temporarily stores application data and instructions for implementing multi-tool manager 102. Network interface 130 communicates with network 104 for passing data and instructions between multi-tool manager 102 and inspection tools 108A-108C. User interface 132 provides an interface to multi-tool manager 102 for users to configure and operate multi-tool manager 102. In one embodiment, user interface 132 includes a graphical user interface (GUI). User interface 132 also includes a keyboard, a monitor, a mouse, and/or any other suitable input or output device.

Memory 122 can include main memory, such as a random access memory (RAM) 126, or other dynamic storage device. Memory 122 can also include a static storage device for application/data memory 128, such as a magnetic disk or optical disk. Memory 122 stores information and instructions to be executed by processor 120. In addition, memory 122 stores data for multi-tool manager 102. One or more processors in a multi-processor arrangement can also be employed to execute a sequence of instructions contained in memory 122. In other embodiments, hardwired circuitry can be used in place of or in combination with software instructions to implement multi-tool manager 102. Thus, embodiments of multi-tool manager 102 are not limited to any specific combination of hardware circuitry and software.

The term “computer readable medium,” as used herein, refers to any medium that participates in providing instructions to processor 120 for execution. Such a medium can take many forms, including but not limited to, non-volatile media, volatile media, and transmission media. Non-volatile media include, for example, optical or magnetic disks. Volatile media includes dynamic memory. Transition media include coaxial cables, copper wire, and fiber optics. Transmission media can also take the form of acoustic or light waves, such as those generated during radio frequency (RF) and infrared (IR) data communications. Common forms of computer readable media include, for example, a floppy disk, a flexible disk, a hard disk, magnetic tape, any other magnetic mediums, a CD-ROM, DVD, any other optical medium, punch cards, paper tape, any other physical medium with patterns of holes, a RAM, a programmable read-only memory (PROM), an electrical programmable read-only memory (EPROM), an electrically erasable programmable read-only memory (EEPROM), any other memory chip or cartridge, or any other medium from which a computer can read.

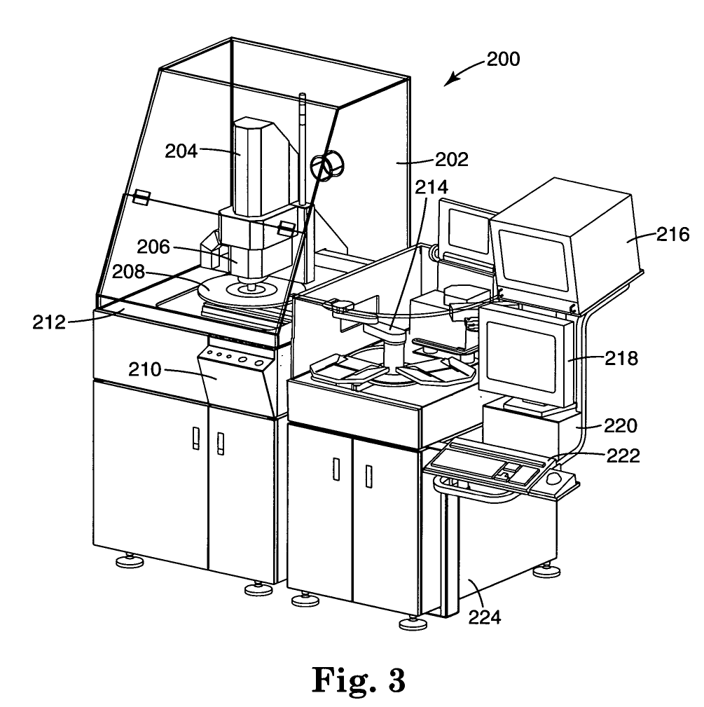

FIG. 3 is a diagram illustrating one embodiment of a semiconductor inspection system 200. In one embodiment, semiconductor inspection system 200 is used for one or more of inspection systems 108A-108C. Semiconductor inspection system 200 includes a hood 202, a camera 204, an inspection light source 206, a wafer test plate 208, a wafer alignment device 212, a control panel 210, a robot 214, a display 216, a system parameters display 218, a computer system or controller 220, a parameter input device 222, and a frame 224.

Camera 204 is used for visual inputting of good die during training and for visual inspection of other unknown quality die during inspection. The camera may be any type of camera capable of high resolution inspection. An example of such a camera is a charge-coupled device (CCD) inspection camera used to capture die or other images during defect analysis. In one embodiment, camera 204 is a high resolution CCD camera that provides high resolution gray scale images for inspection.

Robot 214 provides a wafer to test plate 208 for inspection. Wafer alignment device 212 aligns each and every wafer at the same x, y, and θ location or x, y, z, and θ location. Camera 204 is focused on wafer test plate 208 for inspecting wafers.

Computer controlled illumination, including inspection light source 206, is integrated into and with inspection camera 204 and optics to complete the wafer imaging process. Alternatively, the illumination system may be coupled to camera 204 and optics so long as the illumination system works in conjunction with camera 204. In a strobing environment, the illumination must occur simultaneously or substantially simultaneously with camera 204 shuttering, which is in one example a high speed electronic shuttering mechanism. Alternatively, in a non-strobing environment, the illumination is typically continuous or as needed. Illumination may be by any known illumination means such as high intensity lights, lasers, florescent lights, arc discharge lamps, incandescent lamps, etc.

Parameter input device 222 is for inputting parameters and other constraints or information. These parameters, constraints, and information include sensitivity parameters, geometry, die sizes, die shape, die pitch, number of rows, number of columns, etc. It is contemplated that any form of input device will suffice, including a keyboard, mouse, scanner, infrared or radio frequency transmitter and receiver, etc.

Display 216 is for displaying the view being seen by camera 204 presently or at any previously saved period. The display is preferably a color monitor or other device for displaying a color display format of the image being viewed by camera 204 for the user's viewing, or alternatively viewing an image saved in memory. In addition, the system parameters display 218 is also available for displaying other information as desired by the user, such as system parameters.

Computer system or controller 220 or other computer device having processing and memory capabilities is for saving the inputted good die, developing a model therefrom, and comparing or analyzing other die in comparison to the model based upon defect filtering and sensitivity parameters to determine if defects exist. In addition, computer system 220 is used to perform all other mathematical and statistical functions as well as all operations. In one embodiment, computer system 220 is of a parallel processing DSP environment.

In one embodiment, computer system 220 is communicatively coupled to multi-tool manager 102 through network 104 (FIG. 1). In this embodiment, multi-tool manager 102 can monitor and control all of the operations performed by controller 220. In one embodiment, computer system 220 transmits test results to multi-tool manager 102.

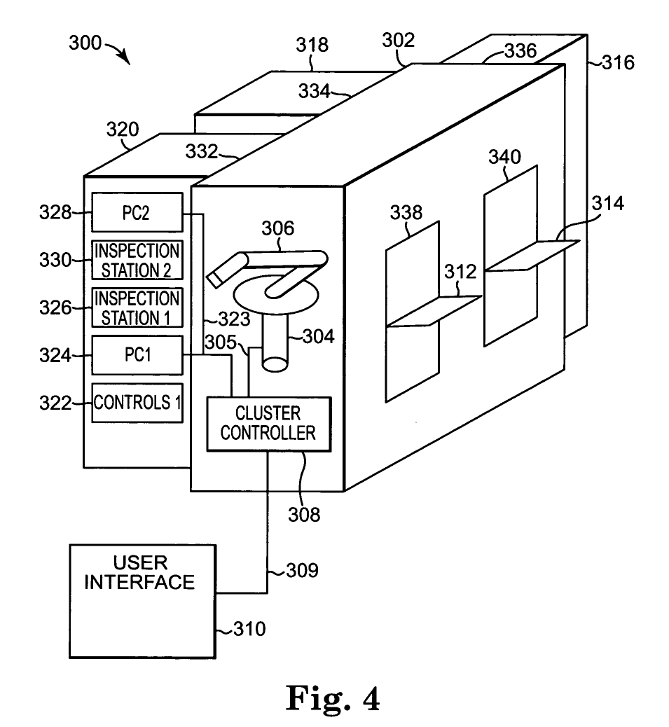

FIG. 4 is a perspective diagram illustrating one embodiment of a semiconductor inspection tool 300. In one embodiment, semiconductor inspection system 300 is used for one or more of inspection systems 108A-108C. Semiconductor inspection tool 300 includes a handler 302, inspection modules 316, 318, and 320, wafer carriers or loadports 312 and 314, and user interface 310. Handler 302 includes a robot 304, a cluster controller 308, and module ports 332, 334, 336, 338, and 340. Robot 304 includes an arm 306. Module 320 includes inspection station one 326, inspection station two 330, personal computer (PC) one 324, PC two 328, and controls one 322.

Semiconductor inspection tool 300 is configured to receive two or more inspection modules, such as modules 316, 318, and 320, which are each configured to receive one or more inspection stations, such as inspection station one 326 and inspection station two 330. Each inspection station can be a defect detection system, metrology system, or review system. The modules are clustered around robot 304 and serviced/scheduled by a single controller, such as cluster controller 308, thereby reducing the handling and inspection data flow costs.

Cluster controller 308 is electrically coupled to user interface 310 through communication link 309, robot 304 through communication link 305, and PC one 324 and PC two 328 through communication link 323. Module 320 is removably coupled to handler 302 at module port 332. Module 318 is removably coupled to handler 302 at module port 334. Module 316 is removably coupled to handler 302 at module port 336. Wafer carrier 312 is removably coupled to handler 302 at module port 338. Wafer carrier 314 is removably coupled to handler 302 at module port 340. In one embodiment, wafer carrier 312 and wafer carrier 314 comprise removable wafer cassettes for holding and transporting semiconductor wafers between semiconductor inspection tool 300 and other wafer processing equipment, such as semiconductor inspection tool 200 (FIG. 3).

In one embodiment, handler 302 can include any suitable number of module ports for removably coupling any suitable number of modules to handler 302. In one embodiment, each module has common controls, such as controls one 322, for providing power, input/output, and other controls for each inspection station in the module, such as inspection station one 326 and inspection station two 330. PC one 324 controls the inspection of wafers on inspection station one 326, and PC two 328 controls the inspection of wafers on inspection station two 330. PC one 324 provides inspection results data for inspection station one 326, and PC two 328 provides inspection results data for inspection station two 330. The inspection results from PC one 324 and PC two 328 are passed to cluster controller 308 through communication link 323.

Cluster controller 308 passes the inspection results to user interface 310 for display. In one embodiment, cluster controller 308 correlates the inspection data received from PC one 324, PC two 328, and other PCs in other modules used to control other inspection stations, to provide a single display of an inspected wafer, including the correlated inspection results derived from the individual inspection results from each inspection station in semiconductor inspection tool 300. Inspection results are displayed on user interface 310. In one embodiment, user interface 310 includes a monitor, keyboard, mouse, and/or any other suitable input/output device for a user to interface with cluster controller 308 to view inspection results.

In one embodiment, cluster controller 308 is communicatively coupled to multi-tool manager 102 through network 104 (FIG. 1). In this embodiment, multi-tool manager 102 can monitor and control all of the operations performed by cluster controller 308. In addition, multi-tool manager 102 can perform all of the functions performed by user interface 310. In one embodiment, cluster controller 308 transmits test results to multi-tool manager 102.

In one embodiment, multi-tool manager 102 is adapted to configure, monitor, control, troubleshoot, enable, disable, and coordinate the inspection of a product between multiple inspection tools, such as inspection tools 200 and 300. In addition, in one embodiment, multi-tool manager 102 receives inspection results from multiple inspection tools and coordinates the inspection results. Multi-tool manager 102, according to one form of the invention, reduces operating costs by providing access to multiple inspection tools from a single location to simplify management of the multiple inspection tools.

Accordingly, the invention as described above and understood by one of skill in the art is simplified, provides an effective, safe, inexpensive, and efficient device, system and process that achieves all the enumerated objectives, provides for eliminating difficulties encountered with prior devices, systems and processes, and solves problems and obtains new results in the art.

In the foregoing description, certain terms have been used for brevity, clearness, and understanding; but no unnecessary limitations are to be implied therefrom beyond the requirement of the prior art, because such terms are used for descriptive purposes and are intended to be broadly construed.

Moreover, the invention's description and illustration is by way of example, and the invention's scope is not limited to the exact details shown or described.

Having now described the features, discoveries and principles of the invention, the manner in which it is constructed and used, the characteristics of the construction, and the advantageous, new and useful results obtained; the new and useful structures, devices, elements, arrangements, parts and combinations, are set forth in the appended claims.

1. A semiconductor inspection system comprising:
a first inspection tool communicatively coupled to a network;
a second inspection tool communicatively coupled to the network; and
a multi-tool manager communicatively coupled to the network, the multi-tool manager configured to monitor the first inspection tool and the second inspection tool through the network.

2. The semiconductor inspection system of claim 1, wherein the multi-tool manager is configured to configure the first inspection tool and the second inspection tool through the network.

3. The semiconductor inspection system of claim 1, wherein the multi-tool manager is configured to control the first inspection tool and the second inspection tool through the network.

4. The semiconductor inspection system of claim 1, wherein the multi-tool manager is configured to troubleshoot the first inspection tool and the second inspection tool through the network.

5. The semiconductor inspection system of claim 1, wherein the multi-tool manager comprises a processor, a memory, and a user interface.

6. The semiconductor inspection system of claim 5, wherein the user interface comprises a graphical user interface.

7. The semiconductor inspection system of claim 1, wherein the first inspection tool comprises a stand alone inspection tool.

8. The semiconductor inspection system of claim 7, wherein the stand alone inspection tool comprises a camera, an inspection light source, and a controller, wherein the controller is adapted to control the camera and the inspection light source to inspect semiconductor wafers.

9. The semiconductor inspection system of claim 1, wherein the first inspection tool comprises a cluster inspection tool.

10. The semiconductor inspection system of claim 9, wherein the cluster inspection tool comprises at least two inspection modules, a load port, a robot, and a cluster controller, wherein the cluster controller is adapted to control the robot to pass semiconductor wafers between the load port and the at least two inspection modules.

11. A semiconductor inspection system comprising:
a multi-tool manager coupled to a network;
a plurality of semiconductor inspection tools, each of the semiconductor inspection tools coupled to the network; and
wherein the multi-tool manager communicates through the network with the plurality of semiconductor inspection tools to control the plurality of semiconductor inspection tools.

12. The semiconductor inspection system of claim 11, wherein the network comprises a local area network.

13. The semiconductor inspection system of claim 11, wherein the network comprises an internet.

14. The semiconductor inspection system of claim 11, wherein each of the semiconductor inspection tools comprise at least one semiconductor wafer inspection system.

15. The semiconductor inspection system of claim 14, wherein the at least one semiconductor wafer inspection system comprises one of a two dimensional front side inspection system, a three dimensional front side inspection system, an edge inspection system, and a back side inspection system.

16. The semiconductor inspection system of claim 14, wherein the at least one semiconductor wafer inspection system comprises one of a metrology system, a wafer bowing system, a microscopy system, a film thickness system, a chemical mechanical polishing dishing system, a chemical mechanical polishing erosion system, a macro critical dimension metrology system, and a micro critical dimension metrology system.

17. The semiconductor inspection system of claim 14, wherein the at least one semiconductor wafer inspection system is configured for inspecting wafers at one of a bare wafer stage, a photolithography stage, an active topography stage, a metal interconnect stage, an etch stage, a chemical mechanical polish stage, and a final passivation stage.

18. A method for inspecting semiconductors, the method comprising:
providing a first inspection tool coupled to a network;
providing a second inspection tool coupled to the network;
providing a multi-tool manager coupled to the network, the multi-tool manager adapted to communicate with the first inspection tool and the second inspection tool through the network; and
operating the first inspection tool and the second inspection tool from the multi-tool manager.

19. The method of claim 18, further comprising:
troubleshooting the first inspection tool and the second inspection tool from the multi-tool manager through the network.

20. The method of claim 18, further comprising:
monitoring the first inspection tool and the second inspection tool from the multi-tool manager through the network.

21. The method of claim 18, further comprising:
enabling the first inspection tool and the second inspection tool from the multi-tool manager through the network.

22. The method of claim 18, further comprising:
disabling the first inspection tool and the second inspection tool from the multi-tool manager through the network.

23. The method of claim 18, further comprising:
transmitting test results from the first inspection tool and the second inspection tool to the multi-tool manager through the network.
